(19) United States
(12) Patent Application Publication
(10) Pub. No.: US 2024/0283217 A1
(43) Pub. Date: Aug. 22, 2024

(54) SURFACE-EMITTING LASER DEVICE WITH CONDUCTIVE THIN FILM AND MANUFACTURING METHOD THEREOF

(71) Applicant: HLJ TECHNOLOGY CO., LTD., Hsinchu County (TW)

(72) Inventors: LI-HUNG LAI, HSINCHU COUNTY (TW); LI-WEN LAI, HSINCHU COUNTY (TW)

(21) Appl. No.: 18/136,923

(22) Filed: Apr. 20, 2023

(30) Foreign Application Priority Data
Feb. 16, 2023 (TW) 112105486

(51) Int. Cl. H01S 5/042; H01S 5/183

(52) U.S. Cl. CPC H01S 5/04253; H01S 5/183

(57) ABSTRACT

A surface-emitting laser device with a conductive thin film includes a first mirror layer, an active layer, a P-type conductive layer, an insulating layer, a thin film structure and a second mirror layer. The active layer is located on the first mirror layer. The P-type conductive layer is located on a surface of a part of the active layer. The insulating layer is located on the first mirror layer and covers the P-type conductive layer, and the insulating layer is provided with a light-emitting hole corresponding to the P-type conductive layer. The thin film structure has conductivity and light transmission. The thin film structure includes a filling part and a covering part. The filling part fills the light-emitting hole and the covering part is located on the insulating layer. The second mirror layer is located on the thin film structure and corresponds to the light-emitting hole.

### CROSS-REFERENCE TO RELATED PATENT APPLICATION

This application claims the benefit of priority to Taiwan Patent Application No. 112105486, filed on Feb. 16, 2023. The entire content of the above identified application is incorporated herein by reference.

Some references, which may include patents, patent applications and various publications, may be cited and discussed in the description of this disclosure. The citation and/or discussion of such references is provided merely to clarify the description of the present disclosure and is not an admission that any such reference is “prior art” to the disclosure described herein. All references cited and discussed in this specification are incorporated herein by reference in their entireties and to the same extent as if each reference was individually incorporated by reference.

### FIELD OF THE DISCLOSURE

The present disclosure relates to a surface-emitting laser device, and more particularly to a surface-emitting laser device with a conductive thin film and a manufacturing method thereof.

### BACKGROUND OF THE DISCLOSURE

Existing surface-emitting laser devices at least include the P-type conductive layer (or N-type conductive layer), the active layer for generating photons, and the upper distributed Bragg reflector (DBR) and the lower distributed Bragg reflector respectively located on both sides of the active layer. A bias voltage is applied to the P-type conductive layer (or N-type conductive layer) to inject current into the active layer for exciting photons, the upper and lower distributed Bragg reflectors are used to form optical resonance (where photons are reflected back and forth in the chamber between the upper and lower distributed Bragg reflectors), and the laser beam is further emitted from the surface of the device.

However, for the surface-emitting laser device with a P-type conductive layer, the existing metal electrode layer is laterally and electrically connected to the P-type conductive layer, but the efficiency of the photon excitation by the active layer may be affected due to long current paths, unconcentrated currents, and blockage of excited photons. In addition, the existing metal electrode layer also has a large internal resistance, which affects the current transmission (injection) to the active layer, and then reduces the efficiency of photon excitation by the active layer.

### SUMMARY OF THE DISCLOSURE

The technical problem to be solved by the present disclosure is to provide a surface-emitting laser device with a conductive thin film and a manufacturing method thereof for addressing the above-mentioned issues in the related art. The existing metal electrode is replaced by a transparent conductive film, the current injection path is shortened by the transparent conductive thin film, and the luminous efficiency is increased, so as to solve problems relating to the existing metal electrode layer blocking light (affecting the light emission), and the internal resistance affecting the luminous efficiency.

For achieving the aforementioned purpose, the present disclosure provides a surface-emitting laser device with a conductive thin film, including a first mirror layer, an active layer, a P-type conductive layer, an insulating layer, a thin film structure and a second mirror layer. The active layer is located on the first mirror layer. The P-type conductive layer is located on a surface of a part of the active layer. The insulating layer is located on the first mirror layer and covers the P-type conductive layer, and the insulating layer is provided with a light-emitting hole corresponding to the P-type conductive layer. The thin film structure has conductivity and light transmission. The thin film structure includes a filling part and a covering part. The filling part fills the light-emitting hole and the covering part is located on the insulating layer. The second mirror layer is located on the thin film structure and corresponds to the light-emitting hole. The second electrode layer is located on the thin film structure and outside the second mirror layer.

In one of the possible or preferred embodiments, a material of the thin film structure is indium tin oxide, metal or a combination thereof.

In one of the possible or preferred embodiments, the thin film structure is a metal mesh, the metal mesh is formed by a plurality of metal wires, and a thickness of the metal mesh ranges from 3 nm to 5 nm.

In one of the possible or preferred embodiments, a reflectance of the first mirror layer is 100%, and a reflectance of the second mirror layer is greater than or equal to 99%.

For achieving the aforementioned purpose, the present disclosure further provides a manufacturing method of surface-emitting laser device with a conductive thin film, including: providing a first mirror layer; providing an active layer on the first mirror layer; providing a P-type conductive layer on a surface of a part of the active layer; providing an insulating layer on the first mirror layer and the insulating layer covering the P-type conductive layer, in which the insulating layer is provided with a light-emitting hole corresponding to the P-type conductive layer; providing a thin film structure having conductivity and light transmission on insulating layer and the P-type conductive layer, and the thin film structure including a filling part and a covering part, in which the filling part fills the light-emitting hole and the covering part is located on the insulating layer; providing a second mirror layer on the thin film structure and the second mirror layer corresponding to the light-emitting hole; providing a second electrode layer on the thin film structure and the second electrode layer located outside the second mirror layer; and providing a first electrode layer under the first mirror layer.

One of the beneficial effects of the present disclosure is that, by virtue of “providing a thin film structure having conductivity and light transmission,” a surface-emitting laser device with a conductive thin film and a manufacturing method thereof provided by the present disclosure can address the technical problem that the existing metal electrode connected to the conductive layer has a long current path, the current is not concentrated, and the internal resistance is large, such that the luminous efficiency of the active layer is affected.

These and other aspects of the present disclosure will become apparent from the following description of the embodiment taken in conjunction with the following drawings and their captions, although variations and modifications therein may be affected without departing from the spirit and scope of the novel concepts of the disclosure.

### BRIEF DESCRIPTION OF THE DRAWINGS

The described embodiments may be better understood by reference to the following description and the accompanying drawings, in which:

FIG. 1 is a top view of a surface-emitting laser device with a conductive thin film according to an embodiment of the present disclosure;

FIG. 2 is a cross-sectional view of the embodiment shown in FIG. 1;

FIG. 3 is a schematic flow chart of a method for fabricating a surface-emitting laser device with a conductive thin film according to an embodiment of the present disclosure;

FIG. 4 is a schematic diagram corresponding to S1 to S3 in the embodiment shown in FIG. 3;

FIG. 5 is a schematic diagram corresponding to S3 in the embodiment shown in FIG. 3;

FIG. 6 is a schematic diagram corresponding to S4 to S5 in the embodiment shown in FIG. 3;

FIG. 7 is a schematic diagram corresponding to S6 in the embodiment shown in FIG. 3; and

FIG. 8 is a schematic diagram corresponding to S7 in the embodiment shown in FIG. 3.

### DETAILED DESCRIPTION OF THE EXEMPLARY EMBODIMENTS

The present disclosure is more particularly described in the following examples that are intended as illustrative only since numerous modifications and variations therein will be apparent to those skilled in the art. Like numbers in the drawings indicate like components throughout the views. As used in the description herein and throughout the claims that follow, unless the context clearly dictates otherwise, the meaning of “a”, “an”, and “the” includes plural reference, and the meaning of “in” includes “in” and “on”. Titles or subtitles can be used herein for the convenience of a reader, which shall have no influence on the scope of the present disclosure.

The terms used herein generally have their ordinary meanings in the art. In the case of conflict, the present document, including any definitions given herein, will prevail. The same thing can be expressed in more than one way. Alternative language and synonyms can be used for any term(s) discussed herein, and no special significance is to be placed upon whether a term is elaborated or discussed herein. A recital of one or more synonyms does not exclude the use of other synonyms. The use of examples anywhere in this specification including examples of any terms is illustrative only, and in no way limits the scope and meaning of the present disclosure or of any exemplified term. Likewise, the present disclosure is not limited to various embodiments given herein. Numbering terms such as “first”, “second” or “third” can be used to describe various components, signals or the like, which are for distinguishing one component/signal from another one only, and are not intended to, nor should be construed to impose any substantive limitations on the components, signals or the like.

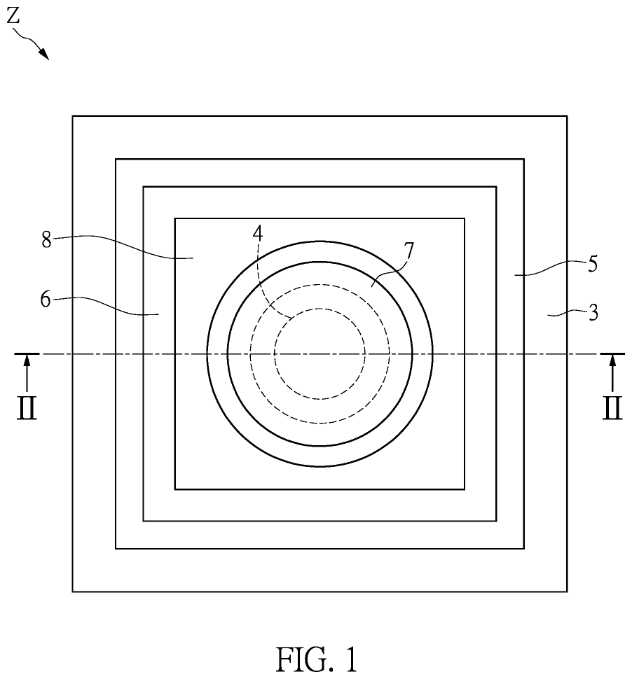

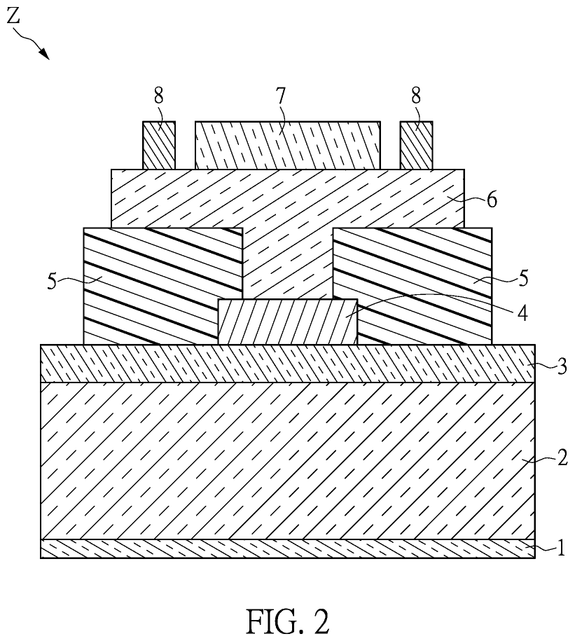

Reference is made to FIG. 1 and FIG. 2. FIG. 1 is a top view of a surface-emitting laser device with a conductive thin film according to an embodiment of the present disclosure and FIG. 2 is a cross-sectional view of the embodiment shown in FIG. 1. A surface-emitting laser device with a conductive thin film Z is provided, including a first electrode 1, a first mirror layer 2, an active layer 3, a P-type conductive layer 4, an insulating layer 5, a thin film structure 6, a second mirror layer 7 and a second electrode layer 8. The first mirror layer 2 is located on the first electrode layer 1. The active layer 3 is located on the first mirror layer 2. The P-type conductive layer 4 is located on a surface of a part of the active layer 3. The insulating layer 5 is located on the first mirror layer 2 and covers the P-type conductive layer 4, and the insulating layer 5 is provided with a light-emitting hole H corresponding to the P-type conductive layer 4. The thin film structure 6 has electrical conductivity and light transmission and is located on the insulating layer 5 and the P-type conductive layer 4. The thin film structure 6 includes a filling part 62 and a covering part 61. The filling part 62 fills the light-emitting hole H and the covering part 61 is located on the insulating layer 5. The second mirror layer 7 is located on the thin film structure 6 and corresponds to the light-emitting hole H. The second electrode layer 8 is located on the thin film structure 6 and is located outside the second mirror layer 7.

The first mirror layer 2, the active layer 3 and the P-type conductive layer 4 can be made of different materials. Due to the complicated structure and material requirements, the structures can be formed by using metal-organic chemical vapor deposition (MOCVD) or molecular beam-oriented epitaxial growth (MBE). The first mirror layer 2 can be a distributed Bragg reflector (DBR) formed by alternately stacking two thin films with different refractive indices, which has high reflectivity, and the material of the first mirror layer 2 can include semiconducting materials, insulating materials or a combination thereof. In the present embodiment, the reflectivity of the first mirror layer 2 is 100%. The active layer 3 generates the light source required for laser resonance. The material of the active layer is determined according to the wavelength of the laser beam L to be generated. For example, when the laser beam to be generated is red light, the material of the active layer can be gallium arsenide. When the laser beam to be generated is near-infrared light, the material of the active layer may be indium gallium arsenide phosphide (InGaAsP) or indium gallium aluminum arsenide (InGaAlAs). When the laser beam to be generated is blue light or green light, the material of the active layer may be indium gallium nitride (InxGa(1-x)N), and the present disclosure is not limited thereto. The P-type conductive layer 4 is used to receive current and transmit the current to the active layer 3 to excite the light source required for the active layer 3 to generate laser resonance. The P-type conductive layer 4 is, for example but not limited to, gallium nitride (GaN). The insulating layer 5 is, for example but not limited to, silicon nitride (Si₃N₄). In certain embodiments, the insulating layer 5 is silicon oxide (SiO₂). The light-emitting hole H has an optical resonant cavity (further details thereof are provided below), and the thin-film structure 6 has electrical conductivity and light transmittance. The thin-film structure 6 includes a filling part 62 and a covering part 61, and the filling part 62 is filled in the light-emitting hole H. In certain embodiments, the thin film structure 6 has high electrical conductivity and high light transmittance, and its conductive property is to assist in transmitting current in the P-type conductive layer 4. The thin film structure 6 does not affect the projection of light because of its high light transmittance, so that the light beam can smoothly resonate back and forth in the optical resonant cavity. In certain embodiments, the thin film structure 6 is formed by sputtering indium tin oxide, such as sputtering ITO. In certain embodiments, the thin film structure 6 is a highly transparent metal sheet. In addition, according to certain embodiments, the thin film structure 6 is a metal mesh, the metal mesh is formed by a plurality of metal wires, and the thickness of the metal mesh ranges from 3 nm to 5 nm. The second reflector layer 7 is also a distributed Bragg reflector, which can be made of dielectric materials, such as being sputtered by TiO₂/SiO₂ or ITO/SiO₂.

With the structure, when a voltage is applied to the second electrode layer 8, the current is transmitted to the P-type conductive layer 4 through the thin film structure 6, and further transmitted to the active layer 3 to excite the active layer 3 to generate the light source required for laser resonance, and the light beam of a specific wavelength (depending on the material of the active layer 3) is reflected back and forth (resonance) in the optical cavity between the first mirror layer 2 and the second mirror layer 7. Due to the high light transmission of the film structure, the back-and-forth reflection of the light beam is not affected, and since the light reflectivity of the second mirror layer 7 is slightly smaller than that of the first mirror layer 2, a part of the light leaks out of the surface-emitting laser device Z and moves along the light path, so as to achieve the laser luminous efficacy.

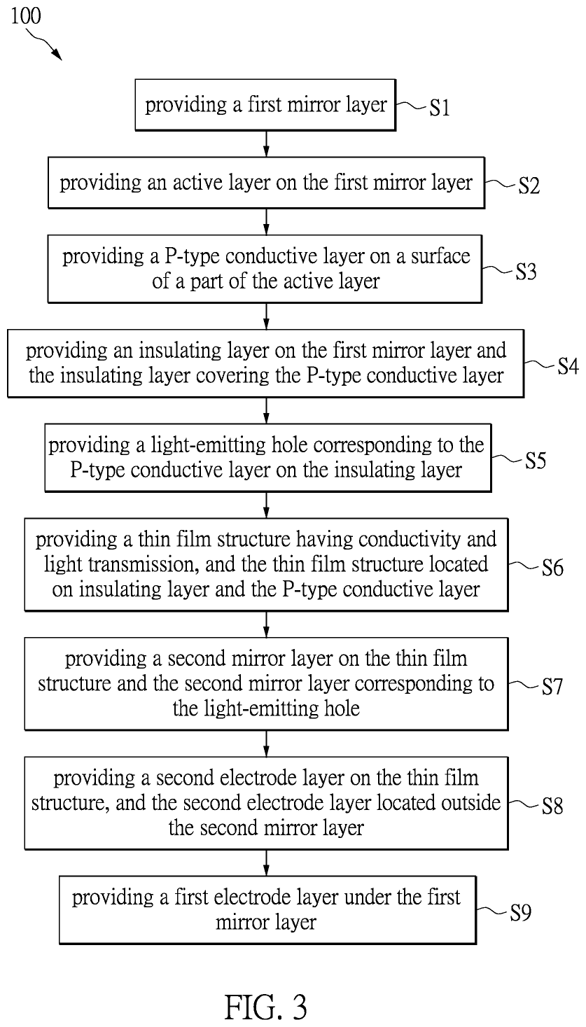

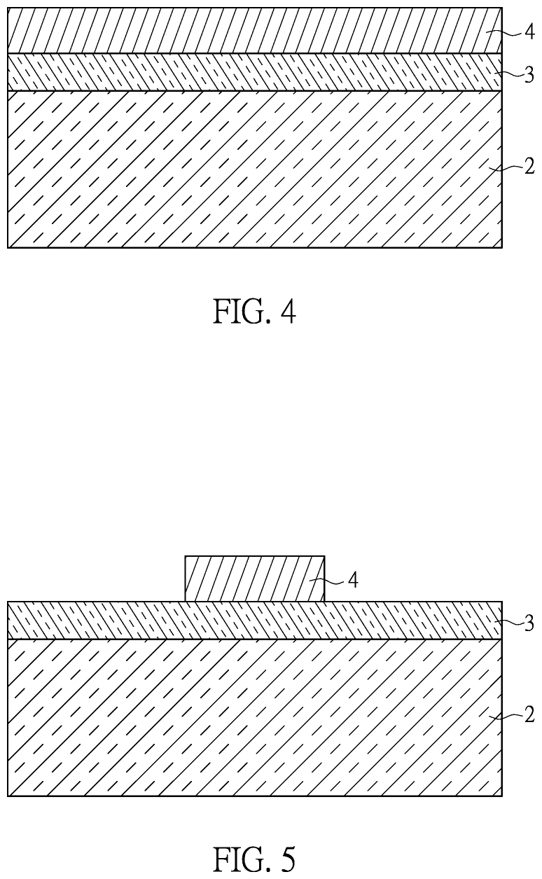

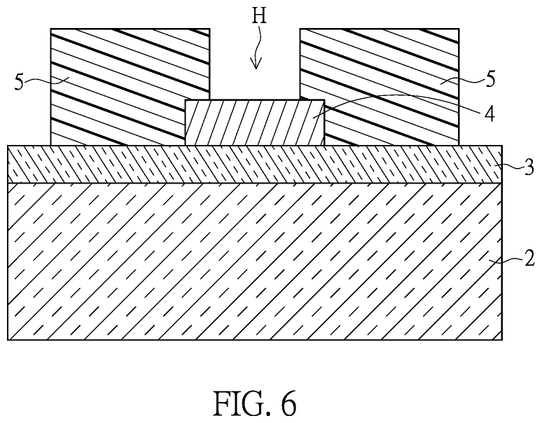

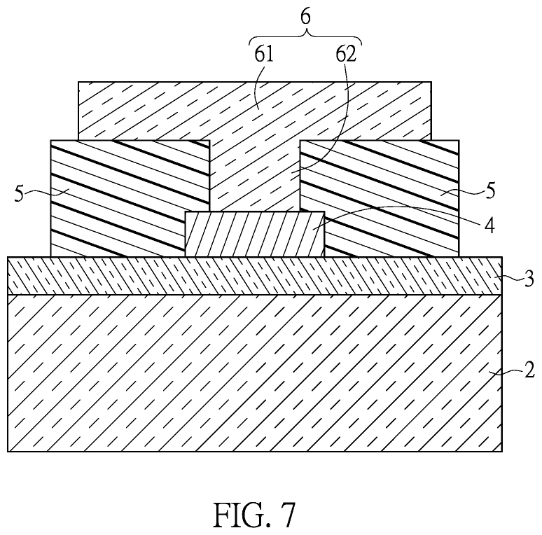

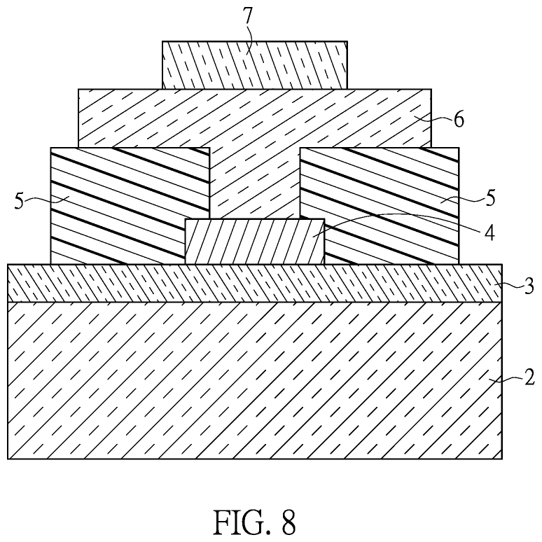

Reference is made to FIG. 3 to FIG. 8. FIG. 3 is a schematic flow chart of a method for fabricating a surface-emitting laser device with a conductive thin film according to an embodiment of the present disclosure, FIG. 4 is a schematic diagram corresponding to S1 to S3 in the embodiment shown in FIG. 3, FIG. 5 is a schematic diagram corresponding to S3 in the embodiment shown in FIG. 3, FIG. 6 is a schematic diagram corresponding to S4 to S5 in the embodiment shown in FIG. 3, FIG. 7 is a schematic diagram corresponding to S6 in the embodiment shown in FIG. 3 and FIG. 8 is a schematic diagram corresponding to S7 in the embodiment shown in FIG. 3.

As shown in FIG. 3, a manufacturing method of surface-emitting laser device with a conductive thin film 100 includes: S1: providing a first mirror layer 2; S2: providing an active layer 3 on the first mirror layer 2; S3: providing a P-type conductive layer 4 on a surface of a part of the active layer 3; S4: providing an insulating layer 5 on the first mirror layer 2 and the insulating layer 5 covering the P-type conductive layer 4; S5: providing a light-emitting hole H corresponding to the P-type conductive layer 4 on the insulating layer 5; S6: providing a thin film structure 6 having conductivity and light transmission on insulating layer 5 and the P-type conductive layer 4, and the thin film structure 6 including a filling part 62 and a covering part 61, in which the filling part 62 fills the light-emitting hole H and the covering part 61 is located on the insulating layer 5; S7: providing a second mirror layer 7 on the thin film structure 6 and the second mirror layer 7 corresponding to the light-emitting hole H; S8: providing a second electrode layer 8 on the thin film structure 6, and the second electrode layer 8 being located outside the second mirror layer 7, and S8: providing a first electrode layer 1 under the first mirror layer 2.

As mentioned above, in certain embodiments, S1 to S3 are completed by metal-organic chemical vapor deposition (MOCVD) or molecular beam epitaxial growth (MBE) due to the complex structure of the surface-emitting laser device Z. In S3, a part of the P-type conductive layer 4 is further etched, and a part of the P-type conductive layer 4 is kept on the active layer 3 as shown in FIG. 5. In certain embodiments, S4 is to cover the insulating layer 5 on the P-type conductive layer 4 and the active layer 3 by means of chemical deposition. In S5, a light-emitting hole H (forming an optical resonant cavity) is provided by etching, as shown in FIG. 6. As shown in FIG. 7, a thin film structure 6 is provided above the insulating layer 5 and the P-type conductive layer 4, and the thin film structure 6 includes a covering portion 61 and a filling portion 62. The filling portion 62 is filled in the light-emitting hole H (referring to FIG. 6). For example, in S6, the thin film structure 6 may be plated by a sputtering process. According to certain embodiments, the conductive film structure is a transparent layer, and its material is ITO. In certain embodiments, the thin film structure 6 is a thin metal sheet with high light transmittance. In addition, according to certain embodiments, the thin film structure 6 is a metal mesh which is formed by a plurality of metal wires, and the thickness of the metal mesh ranges from 3 nm to 5 nm. As shown in FIG. 8, a second mirror layer 7 is provided on the thin film structure 6. For example, in S7, the second mirror layer 7 can be coated on the thin film structure 6 by a sputtering process. The second mirror layer 7 is made of dielectric material, and according to certain embodiments, the second mirror layer 7 is composed of TiO₂/SiO₂. Reference is made to FIG. 2 again. After S8 and S9, the surface-emitting laser device with a conductive thin film Z is completed.

It should be noted that the above-mentioned processes and materials about the first mirror layer 2, the second mirror layer 7, the active layer 3, the P-type conductive layer 4, the insulating layer 5 and the thin film structure 6 are only used as embodiments, and the present disclosure is not limited thereto. In addition, the present disclosure is not limited in terms of the order of the above steps, and the order of the above steps can be adjusted according to the practical requirements.

### Beneficial Effects of the Embodiments

One of the beneficial effects of the present disclosure is that a surface-emitting laser device with a conductive thin film Z and a manufacturing method thereof 100 provided by the present disclosure can improve the luminous efficiency of the surface-emitting laser device Z and reduce the volume of the surface-emitting laser device Z by virtue of “providing a thin film structure 6 having conductivity and light transmission.”

Another of the beneficial effects of the present disclosure is that a surface-emitting laser device with a conductive thin film Z and a manufacturing method thereof 100 provided by the present disclosure can resolve the technical problem that the traditional metal electrode connected to the conductive layer has a long current path, the current is not concentrated, and the internal resistance is large, such that the luminous efficiency of the active layer 3 is affected by virtue of “providing a thin film structure having conductivity and light transmission.”

Furthermore, according to certain embodiments, the thin film structure 6 is ITO, which has a good conductive effect, and is used to replace the traditional metal electrode layer and transmit current in the optical resonant cavity, so that the laser beam is concentrated and resonated in the optical resonant cavity. Since the ITO is transparent and the laser beam can penetrate the ITO, the resonance of the laser beam in the optical resonant cavity is not affected, and the surface-emitting laser device Z can have an optimal luminous effect.

The embodiments were chosen and described in order to explain the principles of the disclosure and their practical application so as to enable others skilled in the art to utilize the disclosure and various embodiments and with various modifications as are suited to the particular use contemplated. Alternative embodiments will become apparent to those skilled in the art to which the present disclosure pertains without departing from its spirit and scope.

What is claimed is:

1. A surface-emitting laser device with a conductive thin film, including:
a first electrode layer;
a first mirror layer located on the first electrode layer;
an active layer located on the first mirror layer;
a P-type conductive layer located on a surface of a part of the active layer,
an insulating layer located on the first mirror layer and covering the P-type conductive layer, wherein the insulating layer is provided with a light-emitting hole corresponding to the P-type conductive layer;
a thin film structure having conductivity and light transmission located on insulating layer and the P-type conductive layer, and the thin film structure including a filling part and a covering part, wherein the filling part fills the light-emitting hole and the covering part is located on the insulating layer;
a second mirror layer located on the thin film structure and corresponding to the light-emitting hole; and
a second electrode layer located on the thin film structure and outside the second mirror layer.

2. The surface-emitting laser device with a conductive thin film according to claim 1, wherein a material of the thin film structure is indium tin oxide, metal or a combination thereof.

3. The surface-emitting laser device with a conductive thin film according to claim 1, wherein the thin film structure is a metal mesh, the metal mesh is formed by a plurality of metal wires, and a thickness of the metal mesh ranges from 3 nm to 5 nm.

4. The surface-emitting laser device with a conductive thin film according to claim 1, wherein a reflectance of the first mirror layer is 100%, and a reflectance of the second mirror layer is greater than or equal to 99%.

5. A manufacturing method of surface-emitting laser device with a conductive thin film, including:
providing a first mirror layer;
providing an active layer on the first mirror layer;
providing a P-type conductive layer on a surface of a part of the active layer;
providing an insulating layer on the first mirror layer and the insulating layer covering the P-type conductive layer, wherein the insulating layer is provided with a light-emitting hole corresponding to the P-type conductive layer;
providing a thin film structure having conductivity and light transmission on insulating layer and the P-type conductive layer, the thin film structure including a filling part and a covering part, wherein the filling part fills the light-emitting hole, and the covering part is located on the insulating layer;
providing a second mirror layer on the thin film structure, the second mirror layer corresponding to the light-emitting hole;
providing a second electrode layer on the thin film structure; the second electrode layer being located outside the second mirror layer; and
providing a first electrode layer under the first mirror layer.

6. The manufacturing method of surface-emitting laser device with a conductive thin film according to claim 5, wherein a material of the thin film structure is indium tin oxide, metal or a combination thereof.

7. The manufacturing method of surface-emitting laser device with a conductive thin film to according to claim 5, wherein the thin film structure is a metal mesh, the metal mesh is formed by a plurality of metal wires, and a thickness of the metal mesh ranges from 3 nm to 5 nm.

8. The manufacturing method of surface-emitting laser device with a conductive thin film according to claim 5, wherein a reflectance of the first mirror layer is 100%, and a reflectance of the second mirror layer is greater than or equal to 99%.
